(19) United States
(12) Patent Application Publication
(10) Pub. No.: US 2004/0142104 A1
(43) Pub. Date: Jul. 22, 2004

(54) Apparatus and method for depositing environmentally sensitive thin film materials

(76) Inventor: Christopher P. Woolley, Sebastapol, CA (US)

Correspondence Address: EDWARD S. SHERMAN, 5698 EAGLE ROCK CT., SANTA ROSA, CA, 95409, US

(21) Appl. No.: 10/752,127

(22) Filed: Jan. 6, 2004

Related U.S. Application Data
(60) Provisional application No. 60/438,472, filed on Jan. 7, 2003.

(51) Int. Cl. C23C 16/00

(52) U.S. Cl. 427/248.1

(57) ABSTRACT

An apparatus and method for depositing thin materials that are sensitive to the environment outside the coating chamber deploys a sealable canister as a take up roll in a roll-to-roll vacuum coating apparatus. A front slot in the canister receives web or film during coating, but is sealed when the coating process is completed, but before the chamber is vented to the atmosphere.

### CROSS REFERENCE TO RELATED APPLICATIONS

The present application claims priority to provisional application having serial No. 60/438,472 filed on Jan. 7, 2003, which is incorporated herein by reference

### BACKGROUND OF THE INVENTION

This invention relates to a method and apparatus for protecting environmentally sensitive thin film materials subsequently they are in deposition by vacuum coating processes, and more particularly to thin films deposited on flexible webs.

Physical and chemical vapor deposition processes are a convenient method of creating thin film and nano-structured materials having unique chemical, physical, electrical and optical properties and useful devices therefrom. While a very wide range of metals, inorganic and organic compounds can be deposited in a vacuum, or near vacuum with controlled concentrations of either specific reactive gases or non-reactive gases the high surface area inherent in thin films can limit the applications of the technology when the materials are reactive to the normal atmosphere outside a deposition chamber. This limitation can be partially overcome when the device or substrate is a small discrete part, for example by using multiple process chambers isolated by interlocks and feed through transfer devices.

However, in many cases it is desirable to coat large, substantially continuous webs or strips of flexible materials with thin films, as the industrial scale equipment for such manufacturing is highly developed.

According it is an object of the invention to provide devices and methods that enable the continuous vacuum coating of flexible webs or strips of material with thin films containing environmentally sensitive materials, and to protect such coated materials from the environment outside the coating machine during subsequent process steps that lead to the ultimate useful device or stable intermediate product.

### SUMMARY OF THE INVENTION

The instant invention provides a way to protect a coated material from being contaminated between one process and another. This makes it easier to manufacture a material that is reactive to the air and needs to be protected between processes. A container is placed in the coating machine with a take up shaft inside the container. The material is wound through the coating machine and is wound up on the take up shaft. When the process is complete the material is inside the container and the container is closed. The container prevents the material inside from being exposed to an atmosphere that will contaminate the material. The container can be moved to the next process or the machine can be set up to run the next process. Once the machine is ready, the container opens and the material inside can go through the next process.

The above and other objects, effects, features, and advantages of the present invention will become more apparent from the following description of the embodiments thereof taken in conjunction with the accompanying drawings.

### BRIEF DESCRIPTION OF DRAWINGS

The various features and advantages of the present invention may be more readily understood with reference to the following detailed description taken in conjunction with the accompanying drawings, wherein like reference numerals designate like structural elements, and in which:

FIG. 1 is a cross-sectional elevation through the coating machine with the transfer container installed.

FIG. 2 is a perspective view of the transfer container.

FIG. 3 is a cross sectional elevation through the transfer container in the open position showing the alternative, or closed, position of components thereof in broken lines, taken through section 300-300′ in FIG. 2.

FIG. 4 is a cross-sectional plan view through the central axis of the take up shaft of the transfer container.

FIG. 5 is a cross-sectional plan view through the central axis of the take up shaft provided further details of the bearing housing and the take up shaft assembly.

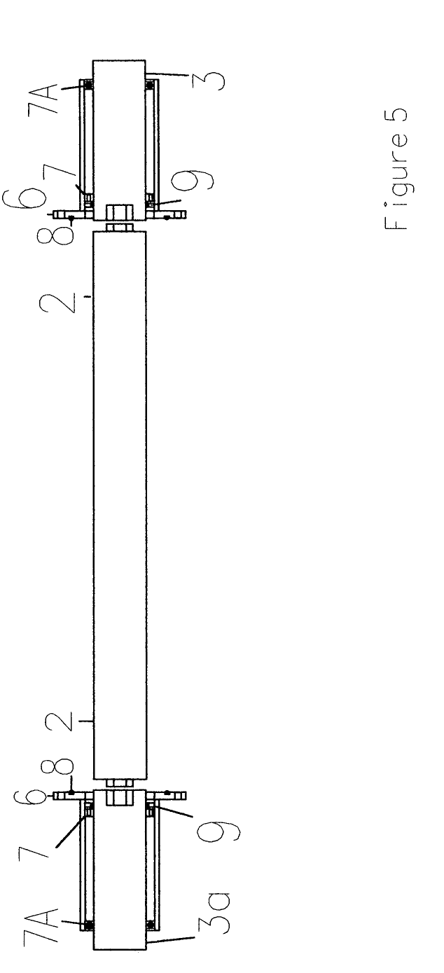

FIG. 6 is an expanded cross-sectional plan view through the central axis of the take up shaft provided further details with a single bearing housing and the connecting portion of the take up shaft assembly.

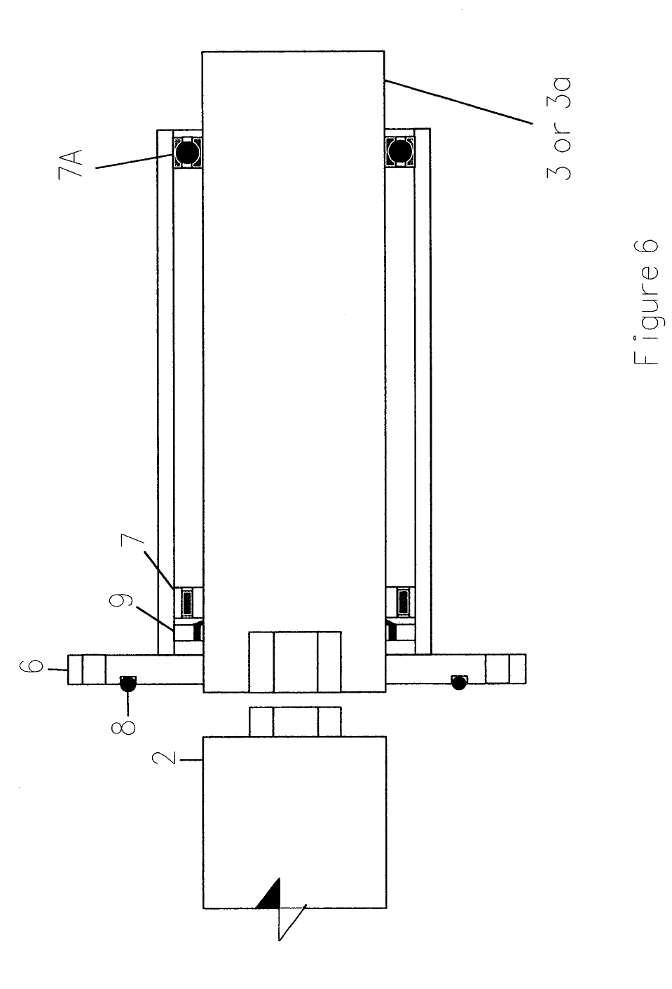

### REFERENCE NUMERALS ALL IN DRAWINGS

(1) Web

(2) Take up shaft

(3) and (3a) Take up shaft end piece

(4) Outer housing

(6) Bearing housing

(7 and 7A) bearings

(8) “O” ring

(9) Shaft seal

(12) Worm gear

(13) Threaded shafts

(14) Brackets to hold idler roller

(15) Driven threaded shaft

(16) A slot cut in the side of the outer housing. The idler roller sits in it and the web passes through it.

(18) Quick disconnect gas fittings

(20) Idler roller

(21) Idler roller shaft

(22) Idler roller with load cells

(25) Chilled roller

(40) Target cathodes that deposit the metals on the web.

(50) The vacuum deposition roll-to-roll coater.

### DETAILED DESCRIPTION

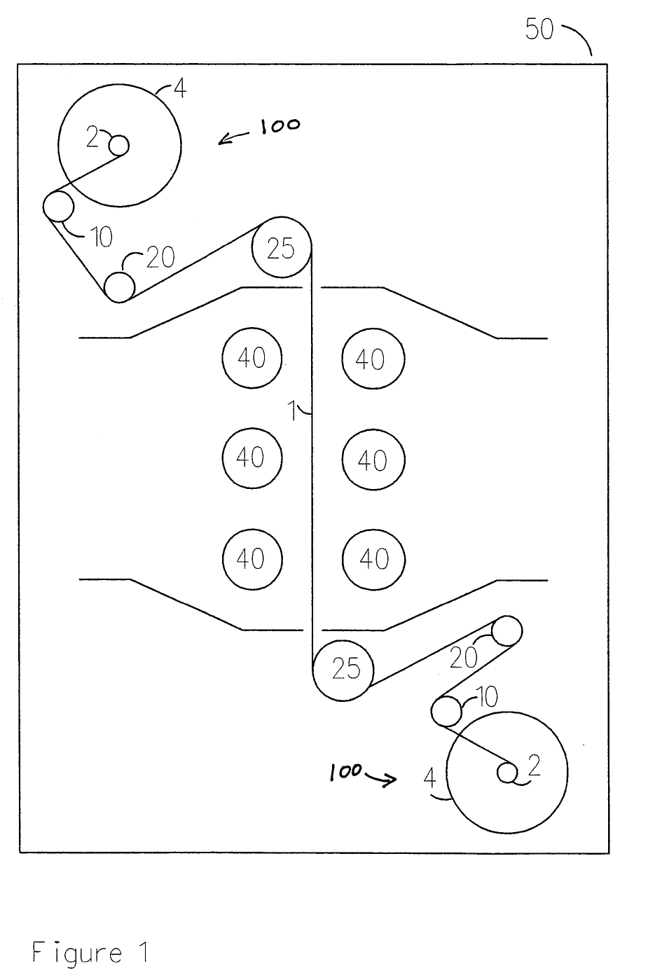

FIG. 1 illustrates a potential configuration for a vacuum coating plant or machine that would utilize the apparatus and methods of the instant invention. Deposition sources 40, preferably sputter cathode magnetrons, are optionally oriented in any direction to deposit thin film materials and that would be sensitive to any component of the atmosphere surrounding the vacuum chamber. Exemplary deposition sources include AC, DC and RF sputter cathodes, thermal evaporation sources, chemical vapor deposition sources and the like.

The uncoated roll of web material is loaded into the vacuum roll coater (50). The web (1) is threaded through the winding system of the coater, Idler roller (20), idler roller with load cells (22), and chilled roller (25). Then the web goes past the deposition sources (40) (for example magnetron sputtering cathode targets), and through the rest of the winding system, and then is attached to the take up shaft (2).

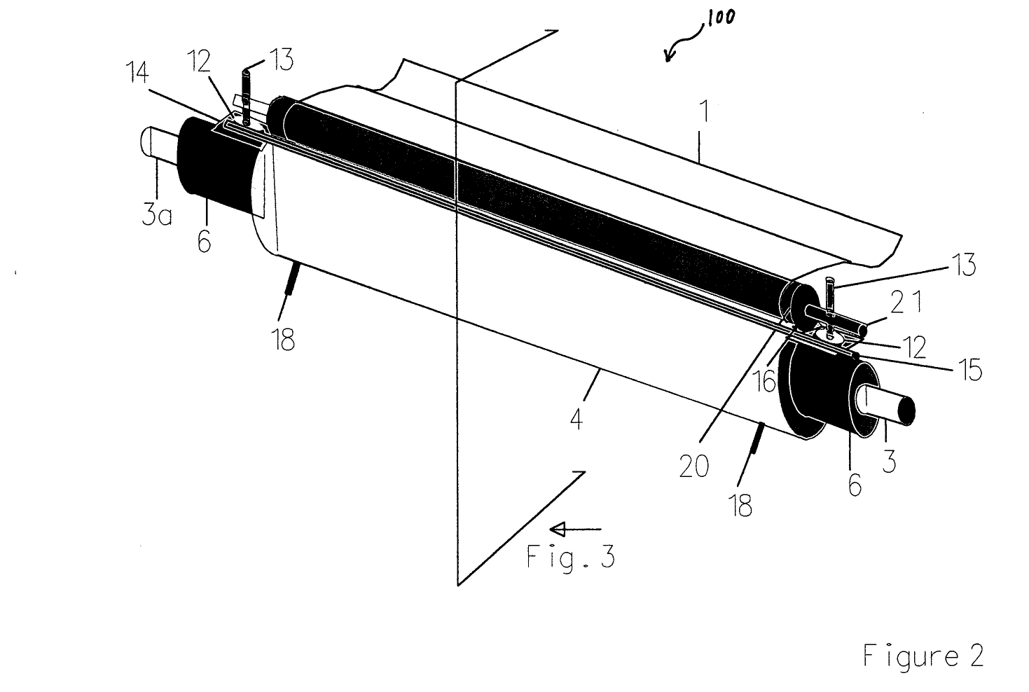

FIG. 2 is a perspective illustration of a take-up shaft and transfer container according to one embodiment in the instant invention that can be used in the conventional vacuum coating chamber illustrated in FIG. 1.

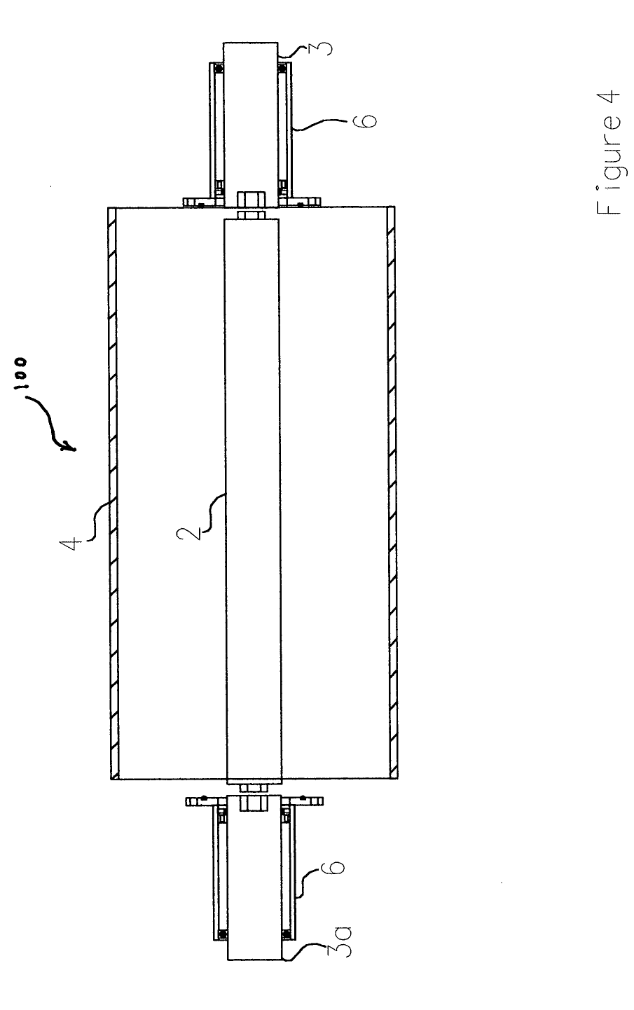

The transfer container consists of a segmented take up shaft (2 and 3 and 3a refer to FIG. 4), enclosed in an outer housing (4). There are bearing housings (6) bolted to both ends of the outer housing (4) and is sealed by an “O” ring seal (8). The bearings (7) and (7A) support the take up shaft end pieces (3 and 3a), and a seal (9) seals the take up shaft end pieces (3 and 3a) from the outer housing (4).

Support structures (14) for the movable engagement of the idler roller (20) from a cylindrical surface of the outer housing (4), preferably included in worm gears (12) adapted to turn threaded shafts (13) that passed through the end portions of the idler roller shaft (21). The support structures is optionally mounted on the bearing housings (6), but can be on another or intermediate structure secured to the end surfaces of the cylindrical housing, so long as it places the idle roll (20) over the slot (16) in the cylinder housing.

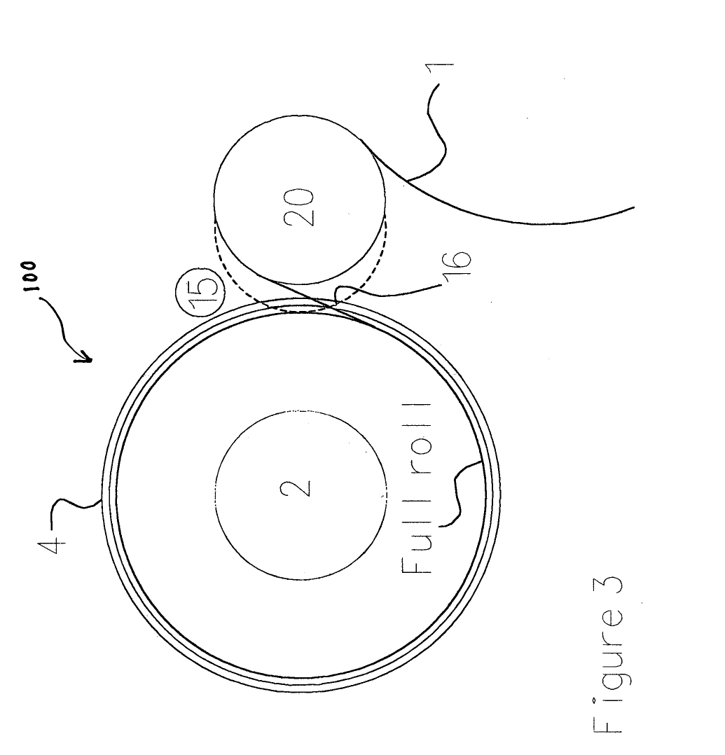

The transfer container opens by moving the idle roller (20) away from the outer housing (4), this opens the slot (16) in the side of the outer housing (4). The flexible web is wound up on the take up shaft (2). When the coating is completed the idler roller (20) is moved back into the slot (16) in the outer housing (4), as illustrated by the dashed line in FIG. 3. By flowing inert gas like argon into the outer housing (4) through one of two gas fittings (16) on the outer housing. A positive pressure can be maintained in the outer housing (4). This will prevent the coated material from becoming contaminated while the transfer container is removed from the coater and placed in a workstation.

The workstation is filled with an inert gas. The transfer container is opened by moving the idler roller (20) away from the outer housing (4). Thus, by utilizing the apparatus of the instant invention to isolate the coated web, in an environment of inert gas immediately after coating, subsequent vacuum manufacturing processes are done without contaminating the coated web.

To accomplish this process one installs a roll of material into a vacuum deposition roll-to-roll coater. Next the coating chamber (50) is pumped down to a base pressure range of 1×10⁻⁵ torr to 1×10⁻⁷ torr. An inert gas, typically Argon, would be supplied to the sputter targets. Sufficient Argon is admitted to raise the pressure to 1×10⁻³ torr. The material would be unwound from one side of the coater and pass by the sputter targets (40) while the targets are powered on. When the coating is complete, the material will have been wound up on a take up shaft (2).

The take up shaft (2) is made up of a removable shaft portion, driven by the conventional roll drive system with a roll-to-roll coating machine. On this shaft is a container (100) having outer housing (4) that has sealed bearings (7) and (7a) as well as and shaft seals (9) on each end. In the side of the container (100) is a slot (16) that the material or web (1) passes through en route to attaching to the take up shaft (2). Above the slot (16) in the container (100) is an idler roller (20) that the material (1) runs over, coming from the machine winding system and to the take up shaft (2). The idler roller (2) is supported by a means to raise and lower it in and out of the slot (16). This can be done with a worm gear assembly, driven by an electric motor, which turns the threaded shaft that turns the gears on each end of the transfer container (100) and the idler roller (20). These gears turn threaded shafts, which raise and lower the idler roller in relation to slot (16).

At the start of the run, the idler roller (20) is in the out position, as illustrated in FIG. 3, away from the container slot (16). When coating process is complete and the coated material (1) has been wound into the container (100). The idler roller (20) is then translated to sealable engage slot (16) in the side of the container (16), as illustrated by the broken line (20a) in FIG. 3. Argon gas is supplied into the container (100) through one, preferably one of two, quick disconnect fittings (18) into the outer housing (4). The Argon gas pressurizes the container (100). Now the vacuum coater can be vented and opened without exposing the coated material to the air (or any contaminating environment). However, it should be appreciated that the vacuum chamber (50) is optionally vented directly with an inert gas, so that the sealing of container (100) can actually occur after such a venting process without contaminating the coated material on the web (1). With the coater (50) opened a second Argon line (one that is free to move away from the coater) is attached to the second quick disconnect fitting (18′) and the first line is removed from fitting (18). Now the transfer container (100) including shaft (2) can be removed from the coater (50) and taken to a glove box or equivalent type workstation where the coated material (1) can be unwound from the take up shaft and wound up onto another shaft and treated so as to reach a stable condition, or sealed in another container. For example, when the desired length of web has been wound up with optional additional layer, such as another foil or cloth, the wound components are cut and put into cylinder and sealed with end caps. At this point, the cylinder can be removed from the glove box and the coated web or foil laminate is protected from contamination.

Thus, it should be appreciated that in other aspects and embodiments of the instant invention the transfer container (100) allows the coating machine to be vented while protecting the material inside it from a contaminating environment. This makes it possible to coat a material that is sensitive to the air (like a metal hydride alloy) and then move it from the coater to a workstation to complete the manufacturing processes without being exposed to the air.

In yet a further aspect and embodiment of the instant invention the transfer container makes it possible to coat multiple layers of different materials without exposing the individual layers to the air, in a machine that was designed to coat only a single material at a time. This is done by coating in a first pass one material, closing the transfer container, venting the coater and changing another materials for subsequent coating passes, that is by again pumping down the coater, opening the transfer container and coating the next material. This can be repeated as many times as is needed.

In another aspect and embodiment of the instant invention, the transfer container can also make it possible to coat both sides of the web in a coater that is designed to coat only one side. This is done by coating one side of the material, closing the transfer container. Venting the coating machine removing the container, turning it around and installing it back into the coater. Pumping down the coater, open the transfer container and coat the other side of the material.

It should be appreciated that the web is optionally a plastic film or sheet, metallic foil or wire mesh.

While the invention has been described in connection with a preferred embodiment, it is not intended to limit the scope of the invention to the particular form set forth, but on the contrary, it is intended to cover such alternatives, modifications, and equivalents as may be within the spirit and scope of the invention as defined by the appended claims.

I claim:

1. A transfer container comprising:
a) a substantially cylindrical housing having a first and second end surface with a longitudinal slot in the outer wall extending between the first and second end surface,
b) a take-up shaft disposed along the central axis of the cylindrical housing,
c) bearing housings disposed on the first and second end surfaces of the cylindrical housing for receiving the take-up shaft,
d) an idler roller having end support structures that define a fixed relationship with respect to the cylindrical housing that provide for the selective movement of the idler roller toward the cylindrical housing for sealing the longitudinal slot there within.

2. A process for transferring environmentally sensitive thin film from a vacuum deposition chamber to a second environmentally control chamber, the process comprising:
a) unwinding a flexible webs substrate in a vacuum coating chamber,
b) taking up the unwound web on a take-up shaft mounted co-axially in a cylindrical housing through a longitudinal slot disposed on outer surface of the housing,
c) depositing one or more thin film layers on the flexible web substrate between the unwinding step and the take-up step,
d) sealing the longitudinal slot in the outer surface of the cylindrical housing,
e) venting the vacuum chamber to atmospheric pressure,
f) removing the cylindrical housing containing the flexible web substrate that is coated with the one or more thin film layers,
g) placing the cylindrical housing within a second environmental chamber,
h) closing the second environmental chamber
i) modifying the atmospheric composition within the second environmental chamber
j) opening the longitudinal slot in the cylindrical housing for removing the web or modifying the thin film coating disposed thereon.

3. The process of claim 2 wherein the atmospheric composition is modified to a gas mixture consisting essentially of hydrogen.

4. The process of claim 2 wherein the atmospheric composition is modified to a gas mixture comprising hydrogen.

5. The process of claim 2 wherein the vacuum chamber is vented to atmospheric pressure by filling with an inert gas.

6. The process of claim 2 wherein the flexible web is a metallic foil.

7. The process of claim 2 wherein the flexible web is a plastic film.

8. The process of claim 2 wherein the flexible web is a wire mesh.
